(19) United States
(12) Patent Application Publication
(10) Pub. No.: US 2023/0170271 A1
(43) Pub. Date: Jun. 1, 2023

(54) METHOD OF MANUFACTURING AN ANCHORING ELEMENT OF A SIC-BASED ELECTRONIC DEVICE, ANCHORING ELEMENT, AND ELECTRONIC DEVICE

(71) Applicant: STMICROELECTRONICS S.r.l., Agrate Brianza (IT)

(72) Inventors: Valeria PUGLISI, Catania (IT); Gabriele BELLOCCHI, Catania (IT); Simone RASCUNA', Catania (IT)

(73) Assignee: STMICROELECTRONICS S.r.l., Agrate Brianza (IT)

(21) Appl. No.: 18/056,104

(22) Filed: Nov. 16, 2022

(30) Foreign Application Priority Data
Nov. 26, 2021 (IT) 102021000029939

(51) Int. Cl. H01L 23/31; H01L 29/16; H01L 21/04

(52) U.S. Cl. CPC H01L 23/3178; H01L 29/1608; H01L 21/045

(57) ABSTRACT

An electronic device, comprising: a semiconductor body of silicon carbide; an insulating layer on a surface of the semiconductor body; a layer of metal material extending in part on the surface of the semiconductor body and in part on the insulating layer; a SiN interface layer on the layer of metal material and the insulating layer; a passivation layer on the interface layer; and an anchoring element that protrudes from the passivation layer towards the first insulating layer and extends in the first insulating layer underneath the interface layer.

### BACKGROUND

### Technical Field

The present disclosure relates to a method of manufacturing an anchoring element of an electronic device, to an anchoring element, and to an electronic device including the anchoring element. In particular, the present disclosure concerns an anchoring element designed to improve the reliability of silicon-carbide (SiC) electronic power devices, where the conditions of use envisage high voltages and entail difficulties in forming trenches.

### Description of the Related Art

The semiconductor industry has been showing considerable interest in silicon carbide (SiC), in particular for the manufacture of electronic components such as diodes or transistors, above all for power applications.

The electronic devices formed in a silicon-carbide substrate, in its various polytypes (for example, 3C—SiC, 4H—SiC, 6H—SiC), have numerous advantages such present numerous advantages such as low on-state output resistance, low leakage current, resistance to high operating temperatures, and high operating frequencies.

However, the development and manufacture of SiC-based electronic devices are limited by factors such as the electrical and mechanical properties of passivation layers (comprised in these electronic devices and, for example, extending over semiconductor bodies of SiC of the electronic devices). In particular, it is known to produce the passivation layers using polymeric materials (e.g., polyimide) that make it possible to withstand high operating temperatures of the electronic devices and have high dielectric strength, for example, higher than 400 kV/mm. In detail, the high dielectric strength of the polymeric materials guarantees that the passivation layers withstand high electrical fields, and therefore high differences of potential across them, without undergoing electrical breakdown, and therefore without becoming electrically conductive.

However, the polymeric materials have high coefficients of thermal expansion (CTE) (e.g., CTE=43e⁻⁶ 1/K for the material polybenzobisoxazole, or PIX), and this causes problems of adhesion of the passivation layer to the SiC, which has a lower coefficient of thermal expansion (CTE=3.8e⁻⁶ 1/K).

In particular, these problems of adhesion between the passivation layer and the SiC may arise during thermal cycling tests (conducted, for example, between approximately −50° C. and approximately +150° C.) or during use of the electronic device, when the latter is subjected to high thermal swings (e.g., it is subjected to differences of operating temperature equal to, or higher than, approximately 200° C.). On account of the large difference in CTE between the passivation layer and the SiC, these high thermal swings generate mechanical stresses at an interface between the passivation layer and the SiC, which can lead to (at least partial) delamination of the passivation layer with respect to the SiC semiconductor body.

In the case where this delamination were to be sufficiently extensive (e.g., such that no portion of the passivation layer is interposed between two metallizations of the electronic device set at different potentials, which are thus separated from one another only by air), electrical discharges may be generated at said interface, leading to damage of the electronic device itself. In particular, the risk of damage of the electronic device increases when the latter is used in reverse-biasing conditions, on account of the high voltage difference (e.g., higher than 1000 V) to be withstood.

Known solutions to this problem comprise the use of a plurality of dielectric layers of materials different from one another (e.g., silicon nitride, silicon oxide, and polyimide in succession to one another) to form a passivation multilayer designed to limit the mechanical stresses at the interface with the SiC semiconductor body.

### BRIEF SUMMARY

According to the present disclosure a method of manufacturing an anchoring element of an electronic device, an anchoring element, and an electronic device including the anchoring element are provided.

For example, in at least one embodiment of the present disclosure, a method of manufacturing an anchoring element of a passivation layer of an electronic device, comprises the steps of: forming, on a surface of a semiconductor body of silicon carbide, a first insulating layer of a first material; forming, in part on the surface of the semiconductor body and in part on the first insulating layer, a layer of metal material; forming, on the layer of metal material and on the first insulating layer, an interface layer of a second material different from the first material; removing selective portions of the interface layer at a distance from the layer of metal material, to form an opening throughout the interface layer, thus exposing the first insulating layer; removing, through the opening, selective portions of the first insulating layer to form a cavity in the first insulating layer at, and underneath, said opening, said cavity having at least one dimension, in a direction parallel to said surface, greater than a corresponding dimension of the opening; and simultaneously providing, on the first insulating layer, in the opening and in the cavity, passivation material thus forming the passivation layer on the first insulating layer and said anchoring element in the opening and in the cavity.

### BRIEF DESCRIPTION OF THE SEVERAL VIEWS OF THE DRAWINGS

For a better understanding of the present disclosure, a preferred embodiment thereof is now described, purely by way of non-limiting example, with reference to the attached drawings, wherein:

FIG. 1 illustrates, in a cross-sectional view, an electronic device of a known type;

FIG. 2 illustrates, in a cross-sectional view, an electronic device according to an embodiment of the present disclosure;

FIGS. 3A and 3B show, in plan view, the electronic device of FIG. 2 according to respective embodiments of the present disclosure;

FIG. 4 illustrates, in a cross-sectional view, a portion of an electronic device according to a further embodiment of the present disclosure;

FIGS. 5A-5C show, in cross-sectional views, steps for manufacturing the electronic device of FIG. 2, according to an embodiment of the present disclosure and limitedly to the manufacture of an anchoring element;

FIG. 6 illustrates, in a cross-sectional view, an electronic device according to a further embodiment of the present disclosure; and

FIGS. 7A-7D show, in cross-sectional views, steps for manufacturing the electronic device of FIG. 6, according to an embodiment of the present disclosure and limitedly to the manufacture of an anchoring element.

### DETAILED DESCRIPTION

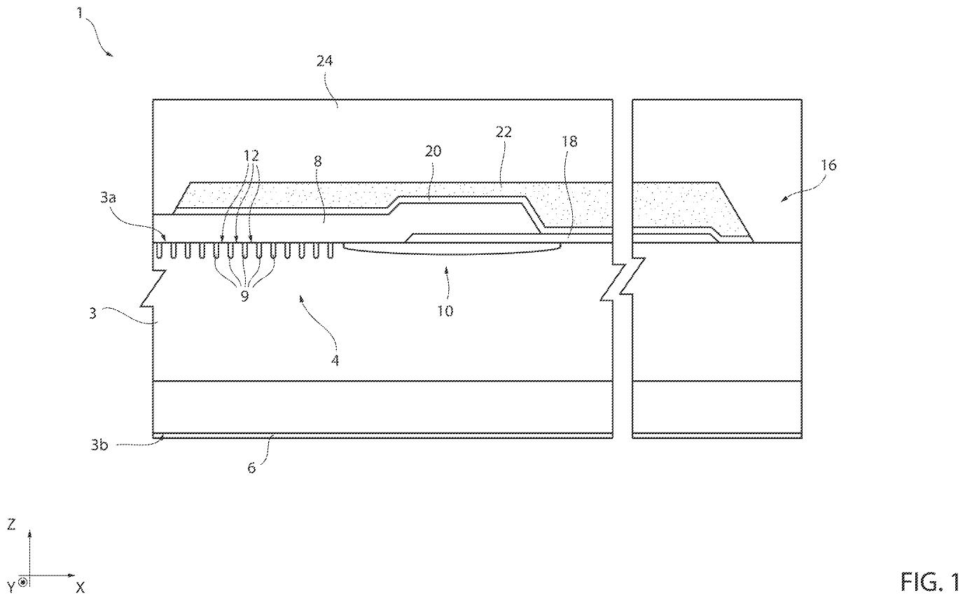

FIG. 1 shows, in lateral cross-sectional view in a (triaxial) Cartesian reference system of axes X, Y, Z, a portion of an electronic device (here by way of example a JBS or Junction-Barrier Schottky diode) 1, which may be of a known type.

The JBS device 1 comprises a semiconductor body 3, of SiC of an N type, provided with a surface 3a opposite to a surface 3b. The semiconductor body 3 includes, for example, a substrate and one or more regions grown epitaxially on the substrate, of an N type and having respective values of doping concentration. The JBS device 1 further comprises multiple junction-barrier (JB) elements 9 in the semiconductor body 3, facing the top surface 3a and each including a respective implanted region in the semiconductor body 3, of a P type, and an ohmic contact on the implanted region, at the level of the top surface 3a of the semiconductor body 3. The JBS device 1 further comprises a first metallization 8, which extends over the top surface 3a, in electrical contact with the junction-barrier elements 9 through the respective ohmic contacts. The JBS device 1 further comprises an edge-termination region 10 (or protection ring), in particular an implanted region of a P type, which surrounds completely the JB elements 9.

Schottky diodes 12 are formed at the interface between the anode metallization 8 and the semiconductor body 3, where semiconductor-metal Schottky junctions are formed. The region of the MPS device 1 that includes the JB elements 9 and the Schottky diodes 12 (i.e., the region contained within the protection ring 10) is an active area 4 of the JBS device 1.

The JBS device 1 further comprises a second metallization 6, which extends over the bottom surface 3b. The first and the second metallizations 8, 6 form, respectively, electrical anode and cathode terminals, which can be biased during use of the JBS device 1.

Extending outside the edge-termination region 10 is an electrically passive region 16.

Extending partially over the edge-termination region 10 is an insulating layer 18, of insulating or dielectric material, in particular silicon oxide (SiO₂).

The first metallization 8 is in electrical contact with a portion of the edge-termination region 10, where the latter is not covered by the insulating layer 18, and likewise extends partially over the insulating layer 18. An interface layer 20, here of silicon nitride (SiN), extends over the first metallization 8 and the insulating layer 18. Furthermore, the JBS device 1 comprises a passivation layer 22, in particular of polyimide, which extends over the interface layer 20. In other words, the interface layer 20 serves as interface between the passivation layer 22 and the underlying layers, here the first metallization 8 and the insulating layer 18. The interface layer 20 may be omitted; however, the Applicant has found that the interface layer 20 improves adhesion of the passivation layer 22 to the underlying layers.

A protection layer 24 of a resin, such as bakelite, extends over the passivation layer 22, protecting the JBS device 1 when inserted in a package (not illustrated).

However, even though the interface layer 20 improves, as has been said, adhesion of the passivation layer 22 to the underlying layers, some critical conditions of use or of thermal or thermo-mechanical testing of the JBS device 1 may cause delamination or partial detachment of the passivation layer 22 from the interface layer 20 (on account of the stress generated by the tests). This in particular occurs in conditions of stress caused by high temperatures of use (e.g., above 150° C.). This effect, in addition to rendering the JBS device 1 structurally brittle, may be a contributing cause of the occurrence of undesired or unintended electrical discharges that affect electrical operation of the JBS device 1. In fact, the Applicant has found that in some process conditions of thermo-mechanical or mechanical stress following upon the assembly process, the interface layer 20 has one or more local cracks throughout its thickness, which, at the first metal layer 8, cause the generation of these undesired or unintended electrical discharges. These problems are all the more evident when the electronic device 1 is subjected to high thermal swings and to high voltage differences in reverse-biasing conditions.

The need is therefore felt to overcome the aforementioned problems as discussed above with respect to the JBS device 1. These aforementioned problems may be addressed by the embodiments of the present disclosure as discussed in detail herein.

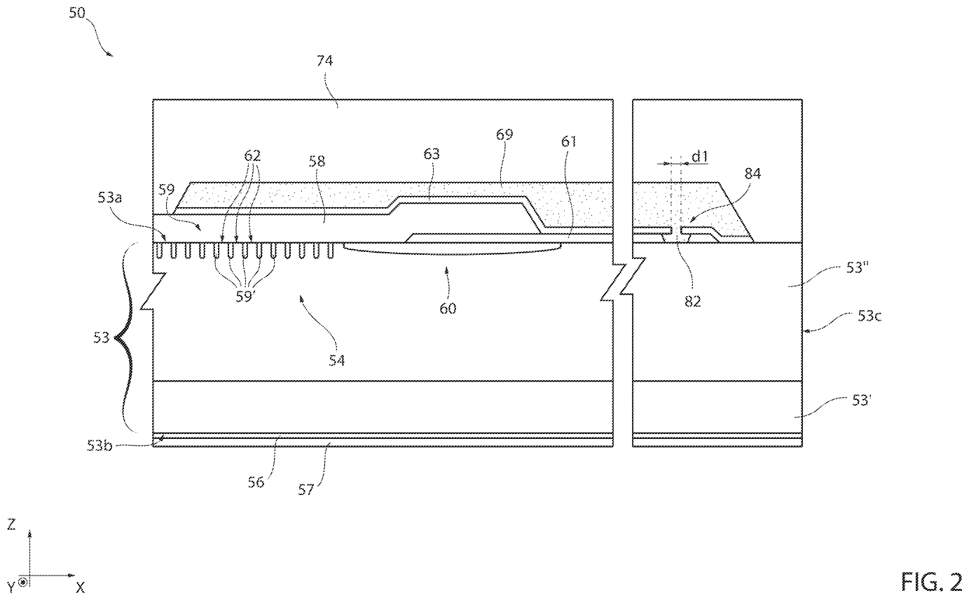

FIG. 2 shows, in lateral cross-sectional view in the same (triaxial) Cartesian reference system of axes X, Y, Z of FIG. 1, an electronic device 50 according to an aspect of the present disclosure. In particular, the device 50 is a JBS diode, similar to what has been described with reference to FIG. 1. However, the present disclosure is not limited to this device and finds application also in other types of electronic devices, in particular power devices, such as, for example, MOSFET, IGBT, MPS, Schottky diode, PN diode, PiN diode, etc.

The electronic device 50 comprises the elements described hereinafter, illustrated with reference to FIG. 2.

A semiconductor body 53 (e.g., including a substrate 53′ and, optionally, one or more epitaxial layers 53″ grown thereon), of SiC of an N type or P type (in what follows non-limiting reference will be made only to an N type), is provided with a front surface 53a opposite to a rear surface 53b along the direction of the axis Z. The semiconductor body 53 includes, in the example illustrated in FIG. 2, the substrate 53′ on which the epitaxial layer 53″ has been grown, having the function of drift layer of the electronic device 50, which are both of SiC of an N type (in particular 4H—SiC, however, other polytypes may be used such as, but not exclusively, 2H—SiC, 3C—SiC and 6H—SiC). For example, the substrate 53′ has a concentration of dopants of an N type comprised between 1·10¹⁹ at/cm³ and 1·10²² at/cm³ and has a thickness, measured along the axis Z between the surfaces 53a and 53b, comprised between 300 μm and 450 μm, and in particular equal to approximately 360 μm. The drift layer 53″ has a respective dopant concentration lower than the dopant concentration of the substrate and a thickness comprised, for example, between 5 and 15 μm.

An ohmic-contact layer 56 (for example, of nickel silicide) extends over the rear surface 53b, and a metallization 57, in this example a cathode metallization, for example, of Ti/NiV/Ag or Ti/NiV/Au, extends over the ohmic-contact region 56.

One or more doped regions 59′ of a P type extend in the semiconductor body 53 (in particular, in the drift layer), facing the top surface 53a; each doped region 59′ houses a respective ohmic contact (not shown and of a known type) such that each doped region 59′ forms a respective junction-barrier (JB) element 59. An edge-termination region, or protection ring, 60, in particular a further doped region of a P type, extends in the drift layer, faces the top surface 53a, and surrounds completely (in plan view, in a plane XY defined by the axes X and Y) the JB elements 59. The edge-termination region 60 may be omitted.

An insulating layer 61 (of insulating or dielectric material, e.g., silicon oxide, or TEOS) extends over the top surface 53a so as to surround completely (in view in the plane XY) the JB elements 59 and to overlap partially the protection ring 60 (when present).

A metallization 58, in this example an anode metallization, for example, of Ti/AlSiCu or Ni/AlSiCu, extends over a portion of the top surface 53a delimited on the outside by the insulating layer 61 (i.e., at the JB elements 59/active area 54) and, partially, over the insulating layer 61.

A passivation layer 69 of polymeric material such as polyamide (e.g., PIX), extends over the anode metallization 58 and over the insulating layer 61.

An interface layer 63, here of silicon nitride (SiN), extends over the anode metallization 58 and over the insulating layer 61, and underneath the passivation layer 69. In other words, the interface layer 63 serves as interface between the passivation layer 69 and the underlying layers, here the metallization 58 and the insulating layer 61, and favors adhesion of the overlying passivation layer 69.

One or more Schottky diodes 62 are formed at the interface between the semiconductor body 53 and the anode metallization 58, and the Schottky diodes 62 are lateral to the doped regions 59′. In particular, (semiconductor-metal) Schottky junctions are formed by portions of the semiconductor layer 53 in direct electrical contact with respective portions of the anode metallization 58.

Furthermore, each ohmic contact extending in the respective doped region 59′ provides an electrical connection having a value of electrical resistivity lower than the value of electrical resistivity of the doped region 59′ that houses it. The JB elements 59 are therefore P-i-N diodes.

The region of the electronic device 50 that includes the JB elements 59 and the Schottky diodes 62 (i.e., the region delimited by the protection ring 60) is an active area 54 of the electronic device 50.

Present outside the active area 54, i.e., beyond the edge-termination region 60, is a side surface 53c of the semiconductor body 53, for example, extending substantially orthogonal to the top surface 53a. The side surface 53c is formed following upon a step of dicing or singulation of a SiC wafer wherein a plurality of electronic devices 50 are obtained. The dicing step has the function of separating one electronic device 50 from another device 50 of the same wafer. Dicing is performed at a scribe line (not shown) of the SiC wafer from which the electronic device 50 is obtained. This scribe line surrounds at a distance, in the plane XY, the active region 54, the protection ring 60, and the insulating layer 61.

A protection layer 74, of a resin, such as, for example, bakelite, extends over the passivation layer 69, protecting the electronic device 50 when inserted in a package (not illustrated).

According to an aspect of the present disclosure, the passivation layer 69 has an anchoring element 82 that protrudes from the passivation layer 69 (in particular, along the direction of the axis Z) and extends in the insulating layer 61, until it reaches the top surface 53a of the semiconductor body 53. The anchoring element 82 anchors and fixes the passivation layer 69 to the insulating layer 61. The anchoring element 82 is integral to the passivation layer 69 and, in particular, is an extension of the passivation layer itself. The anchoring element 82 therefore extends from the passivation layer without interruptions and without interfaces and is of the same material as the passivation layer. In other words, the anchoring element 82 and the passivation layer 69 form a single or monolithic body.

The anchoring element 82 extends through an opening 84 made through the interface layer 63. The opening 84 has a shape chosen freely in the design stage, for example, a circular, oval, or polygonal shape, with a diameter d₁ of a few microns, for example, between 2 and 5 μm.

The anchoring element 82 is formed outside the active area 54, and in particular outside the edge-termination region 60; in other words, the anchoring element 82 is interposed between the edge-termination region 60 and the side surface 53c. In the case where the edge-termination region 60 were not present, the anchoring element 82 is formed outside the active area 54, i.e., between the active area 54 and the side surface 53c in an electrically passive region of the device.

The anchoring element 82 is patterned so as to fix the passivation layer 69 to the insulating layer 61 and is designed to prevent and/or impede delamination and/or detachment of the passivation layer 69.

In particular, the anchoring element 82 is housed and arranged slotted into a housing or cavity extending in the insulating layer 61 so as to couple the passivation layer 69 and the insulating layer 61 together and render them integral to one another. The cavity that houses the anchoring element 82 has a shape complementary to the shape of the anchoring element 82. In other words, the anchoring element 82 fills completely the cavity that houses it.

In an embodiment, the anchoring element 82 has dimensions, in the cross-sectional view of FIG. 2 and measured along the axis X, that increase the greater the distance (along the axis Z) from the passivation layer 69.

In a different embodiment, the anchoring element 82 has a first dimension, in the cross-sectional view of FIG. 2 and measured along the axis X, at the opening 84; the first dimension coincides with the aforementioned diameter d₁ of the opening 84. The anchoring element 82 moreover has a second dimension, in the cross-sectional view of FIG. 2 and measured along the axis X, within the insulating layer 61. The second dimension is greater than the first dimension (for example, but not exclusively, twice as large, i.e., 2·d₁). Within the insulating layer 61, the anchoring element 82 may have any geometrical shape chosen in the design stage, with dimensions (once again considered in the cross-sectional view of FIG. 2 and measured along the axis X) that are variable, but in any case larger than the aforementioned first dimension d₁ at the opening 84.

It is evident that, within the insulating layer 61, the anchoring element 82 may have, in addition or as an alternative to what has been said above with respect to the dimensions along X, a further dimension measured along the axis Y greater than a corresponding dimension (once again measured along the axis Y) of the opening 84.

In this way, since the anchoring element 82 extends underneath the opening 84 and has at least one dimension, in the plane XY, larger than a corresponding dimension, in the plane XY, of the opening 84, the anchoring element 82 has the purpose of fixing the passivation layer 69, which is thus constrained in its movements along the axis Z, therefore preventing any delamination or detachment.

In a further embodiment, within the insulating layer 61, the anchoring element 82 may have, locally, dimensions equal to or smaller than the aforementioned first dimension but, in any case, has at least one portion having a dimension larger than the aforementioned first dimension.

In the example of FIG. 2, the portion of the anchoring element 82 that extends within the insulating layer 61 has (in the cross-sectional view and along the axis X) a trapezoidal shape, with the major side directly facing the interface layer 63 and the minor side in contact with the top surface 53a of the semiconductor body. In further embodiments, not illustrated, the portion of the anchoring element 82 that extends within the insulating layer 61 has (in the cross-sectional view and along the axis X) a rectangular or generically polygonal shape, or an oval shape, or a generically curved or curvilinear shape.

According to a further embodiment, the anchoring element 82 does not extend through the insulating layer 61 throughout the thickness of the latter, but terminates within the insulating layer 61, at a distance from the top surface 53a of the semiconductor body. Also in this case, the shape and dimensions may be chosen similarly to what has been described previously.

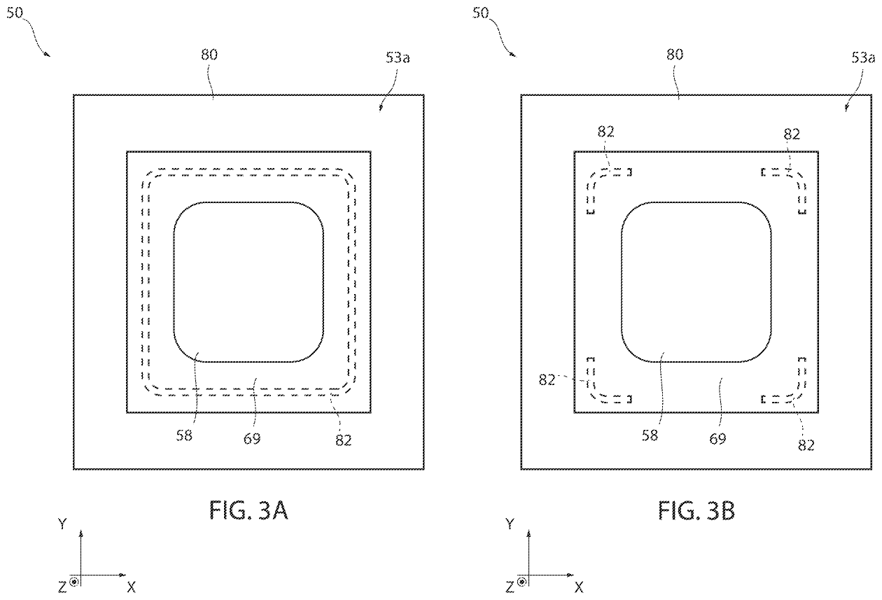

FIGS. 3A and 3B show schematically the electronic device 50 in top plan view (in the plane XY), according to respective embodiments.

With reference to FIG. 3A, the anchoring element 82 extends in the plane XY so as to surround completely the anode metallization 58. In the view in the plane XY of FIG. 3A, the anchoring element 82 is annular and defines a closed polygonal shape, and in greater detail a square shape with rounded corners (even though different shapes are also possible, such as a circular shape, a rectangular shape or a generically polygonal or irregular shape). As shown in FIG. 3A, the anchoring element 82 is a continuous, unitary layer of material that continuously extends around the anode metallization 58, and, as discussed above, has the closed polygonal shape.

With reference to FIG. 3B, the electronic device 50 comprises a plurality of anchoring elements (all of which are similar to the anchoring element 82 described previously and are therefore designated by the same reference number). The anchoring elements 82 extend at a distance from one another at the top surface 53a, at respective portions of the top surface 53a, at a distance from one another. For example, the view in the plane XY of FIG. 3B shows four anchoring elements 82, which are separate, distinct, and discrete from each other, arranged around the anode metallization 58 so as to be at equal angular distances apart with respect to the anode metallization 58, and in greater detail arranged at corners of an ideal square geometrical shape. Other arrangements of different numbers of anchoring elements are, however, possible (e.g., four discrete anchoring elements that are instead along sides of the ideal square geometrical shape, three discrete anchoring elements that are along the corners and sides of the ideal square geometrical shape, or one or more anchoring elements may be arranged in different configurations or arrangements).

While not shown in FIGS. 3A and 3B, in some embodiments, a plurality of the anchoring elements 82 may be separate, distinct and discrete anchoring elements that are circular in shape that are arranged around the anode metallization 58. These separate, distinct, and discrete anchoring elements 82 may be similar or like dots that trace along a geometrical shape (e.g., square, circle, etc.), which may be the ideal square geometrical shape as discussed above.

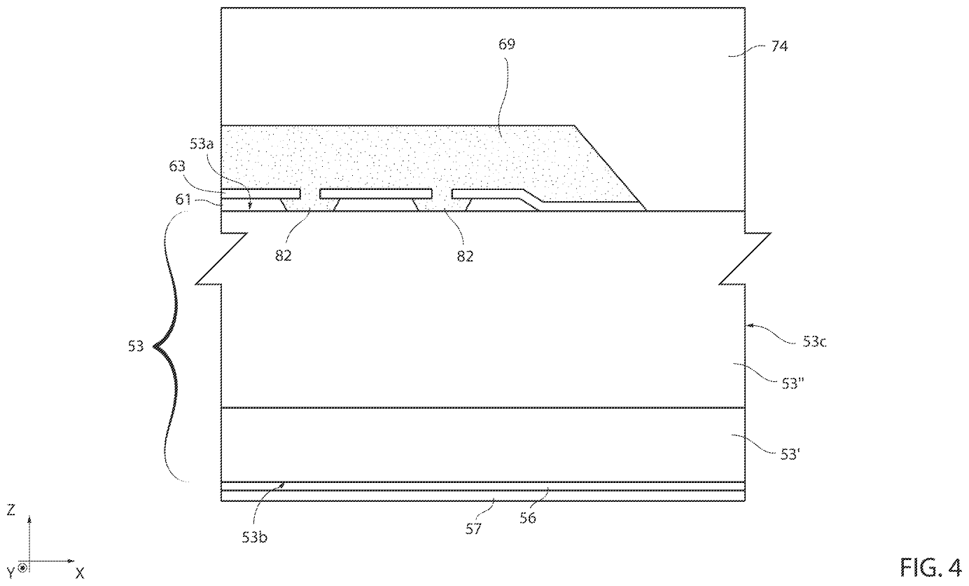

It is evident that, in an embodiment alternative to that of FIG. 2, two or more anchoring elements 82 may be present set alongside one another. For example, as illustrated in FIG. 4 (where only one portion of an electronic device similar to the electronic device 50 is represented), two anchoring elements 82 extend in the insulating layer 61 at a mutual distance apart from one another, along the axis X, equal to a few microns or a few tens of microns, for example between 5 μm and 20 μm. One, some or all of the anchoring elements 82 of this plurality of anchoring elements 82 extend within the insulating layer 61 throughout the thickness (along Z) of the latter, or only partially within the insulating layer 61, terminating in the insulating layer 61 without reaching the top surface 53a.

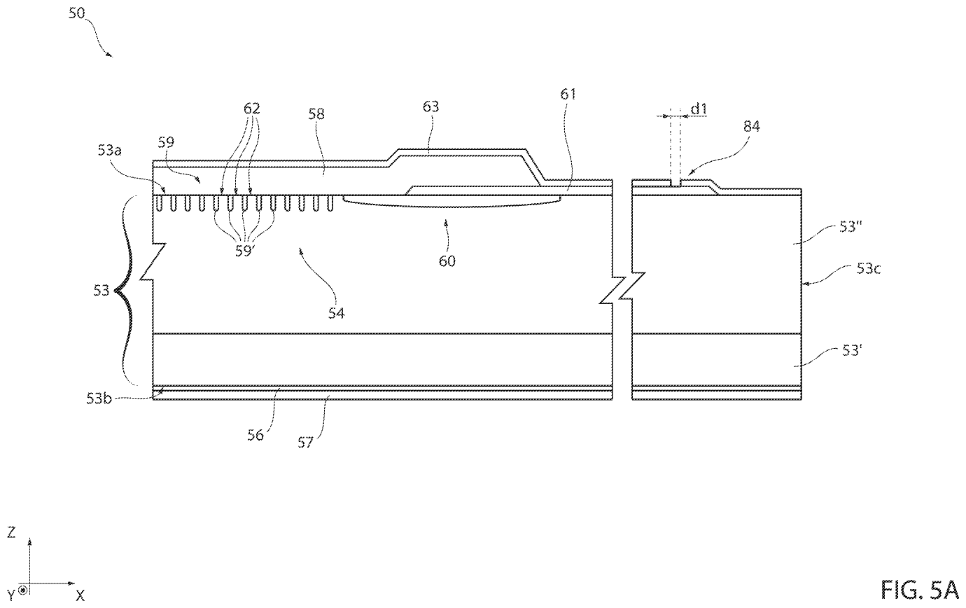

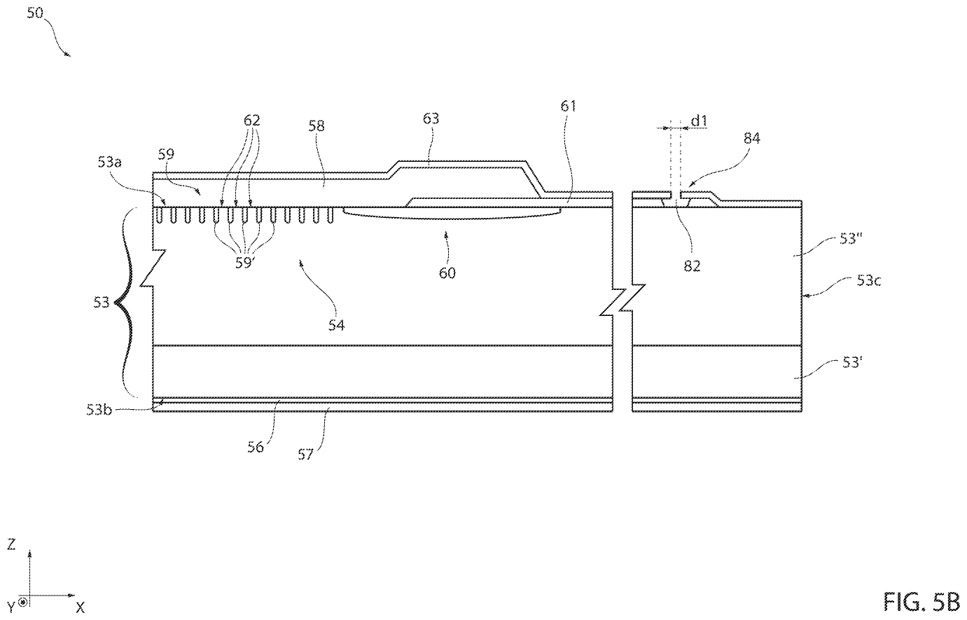

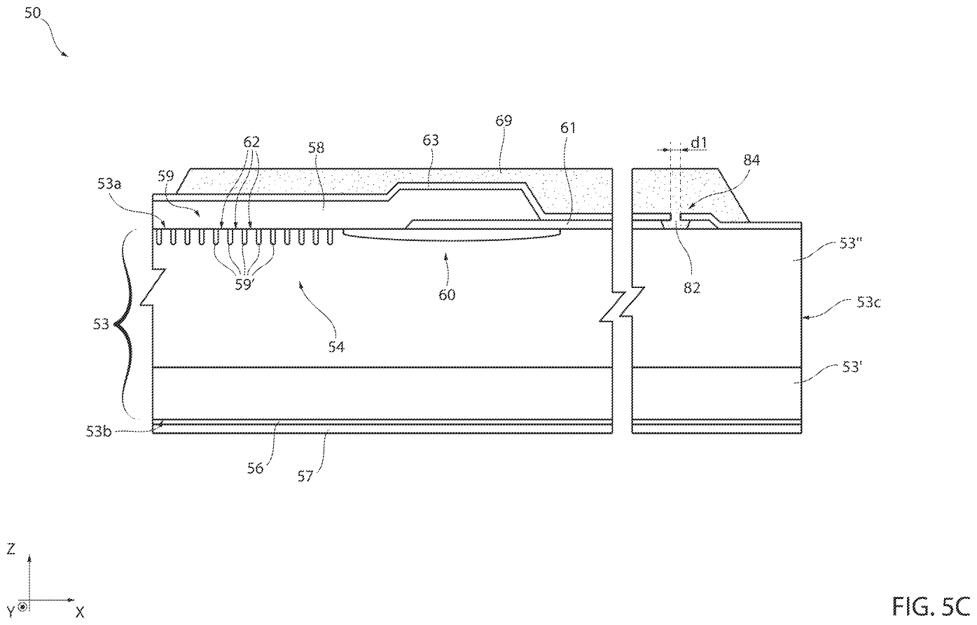

Steps for manufacturing the electronic device 50 of FIG. 2 (similarly applicable to the embodiment of FIG. 4) are described below, with reference to FIGS. 5A-5C and limitedly to the steps for formation of the anchoring element 82. FIGS. 5A-5C are represented in the same triaxial system as that of FIG. 2.

With reference to FIG. 5A, a wafer is provided that includes the SiC semiconductor body 53, following upon manufacturing steps designed to form elements of the electronic device 50 described previously (and not discussed here any further) and identified by the same reference numbers.

The interface layer 63 is selectively etched to form the opening 84. For this purpose, a photoresist or etching mask is for example provided and, by lithographic and etching steps per se known, the opening 84 is formed having the shape, dimensions, and location discussed previously. The opening 84 extends through the interface layer 63 throughout the thickness of the latter, exposing a respective surface portion of the insulating layer 61.

Next, FIG. 5B, an etch of the insulating layer 61 is performed through the opening 84 formed previously. The etch is, for example, of a wet type and, if an etching chemistry is used that is selective with respect to the material of the insulating layer 61 (e.g., hydrofluoric acid in the case of silicon oxide), which therefore does not remove the interface layer 63, it is possible to carry out said etch in the absence of a further etching mask. In this case, it is the interface layer 63 that forms the etching mask. Otherwise, it is possible to use a mask similar to the one used for the step of formation of the opening 84.

Etching of the insulating layer 61 is of an isotropic type and, underneath the interface layer 63, removes the material of the insulating layer both vertically (along Z) and horizontally (in the plane XY). The etch is, for example, a timed etch and is interrupted according to the type of shape that it is desired to give to the anchoring element 82. In the embodiment of FIG. 5B, etching proceeds until the top surface 53a of the semiconductor body 53 is exposed. As has been said, etching proceeds also laterally (along the axis X). A cavity 86 is thus formed in the insulating layer 61.

Then, FIG. 5C, the passivation layer 69 is formed. The polymeric material, which is liquid or semi-liquid, is applied on the wafer and distributed through spinning on the interface layer 63. During this process, the polymeric material penetrates through the opening 84 and fills completely both the cavity 86 and the opening 84. Then a thermal process is carried out until the polymeric material hardens to form the passivation layer 69 (curing process) and, simultaneously, the anchoring element 82. The polymeric material is, for example, polyimide.

The manufacturing process then continues with subsequent steps to form further elements of the electronic device 50, not described here in detail (for example, the ohmic-contact layer 56 and the cathode metallization 57).

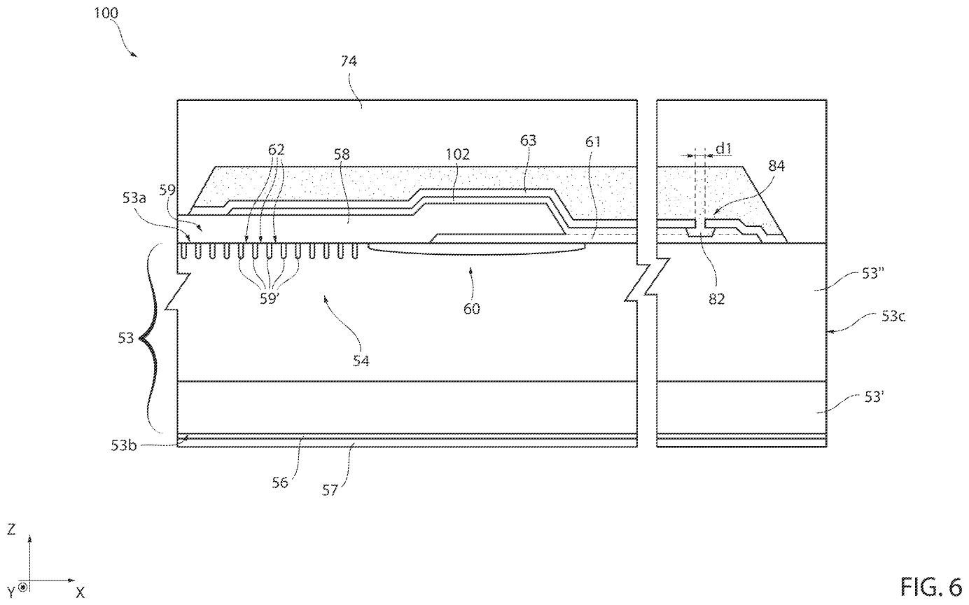

FIG. 6 illustrates an electronic device 100 according to a further embodiment of the present disclosure. The electronic device 100 is represented in the same (triaxial) cartesian reference system of axes X, Y, Z of FIG. 1 and FIG. 2. In particular, the electronic device 100 is a JBS diode, similar to what has been described with reference to FIGS. 1 and 2. However, also in this case, the present disclosure is not limited to a JBS device and finds application also in other types of electronic devices, in particular power devices, such as MOSFET, IGBT, MPSs, Schottky diode, PN diode, PiN diode, etc.

Elements of the electronic device 100 common to the electronic device 50 of FIG. 2 are designated by the same reference numbers and will not be described any further.

In particular, the electronic device 100 comprises, in addition to what has been described for the electronic device 50, a further insulating layer 102, in particular of a dielectric or insulating material, such as, for example, silicon oxide. In particular, the material of the insulating layer 102 is the same as the one used for the insulating layer 61. The insulating layer 102 has, for example, a thickness, along the axis Z, comprised between 0.5 and 2 μm.

The insulating layer 102 extends over the anode metallization 58 and the insulating layer 61 laterally to the anode metallization 58.

The interface layer 63 is optional and, if present, extends over the insulating layer 102; the passivation layer 69 extends over, and in contact with, the interface layer 63 if present; alternatively, the passivation layer 69 extends over, and in contact with, the insulating layer 102.

According to the embodiment of FIG. 6, the passivation layer 69 has, similarly to the embodiment of FIG. 2, the anchoring element 82 that protrudes from the passivation layer 69 (in particular, along the direction of the axis Z). However, in this case, the anchoring element 82 extends completely within the insulating layer 102 (i.e., throughout the thickness, along Z, of the insulating layer 102) and only partially within the insulating layer 61 (terminating in the insulating layer 61), without reaching the top surface 53a of the semiconductor body 53. The anchoring element 82 anchors and fixes the passivation layer 69 both to the insulating layer 102 and to the insulating layer 61. The anchoring element 82 is integral to the passivation layer 69 and in particular is an extension of the passivation layer itself. The anchoring element 82 therefore extends from the passivation layer without interruptions and without interfaces and is of the same material as the passivation layer. In other words, the anchoring element 82 and the passivation layer 69 form a single or monolithic body.

In the case where the interface layer 63 is present, the anchoring element 82 extends through the opening 84 made through the interface layer 63. The opening 84 has a shape chosen freely in the design stage, for example a circular, oval, or polygonal shape, with a diameter d₁ equal to a few microns, for example between 2 and 5 μm.

The anchoring element 82 is formed outside the active area 54, and in particular outside the edge-termination region 60 and at a distance from the anode metallization 58. In other words, the anchoring element 82 is interposed between the edge-termination region 60 and the side surface 53c. In the case where the edge-termination region 60 is not present, the anchoring element 82 is formed outside the active area 54, i.e., between the active area 54 and the side surface 53c in an electrically passive region of the device and at a distance from the anode metallization 58.

In particular, the anchoring element 82 is housed and arranged slotted into a housing or cavity extending in the insulating layer 102 and in the insulating layer 61 so as to couple the passivation layer 69 and the insulating layers 102 and 61 together and render them integral to one another. The cavity that houses the anchoring element 82 has a shape complementary to the shape of the anchoring element 82. In other words, the anchoring element 82 fills completely the cavity that houses it.

The anchoring element 82 has dimensions that have already been discussed with reference to FIG. 2 and are not repeated here for brevity.

According to a further embodiment, not illustrated, the anchoring element 82 extends exclusively (in part or completely) in the insulating layer 102 (therefore terminating within the insulating layer 102 or at the interface between the insulating layer 102 and the underlying insulating layer 61).

According to a further embodiment, not illustrated, the anchoring element 82 extends throughout the thickness of the insulating layer 102 and throughout the thickness of the insulating layer 61.

According to a further embodiment, not illustrated, a plurality of anchoring elements 82 may be present, similar to what has been described with reference to FIG. 4. One, some or all of the anchoring elements 82 of this plurality of anchoring elements 82 extend exclusively within the insulating layer 102 (and not the insulating layer 61), or throughout the thickness of the insulating layer 102 and throughout the thickness of the insulating layer 61, or throughout the thickness of the insulating layer 102 and partially within the insulating layer 61.

In the embodiment of FIG. 6, the insulating layer 102 has the function of forming a further interface between the interface layer 63 and the anode metallization 58, to obtain an electrical insulation at the anode metallization 58 in case of cracking of the interface layer 63.

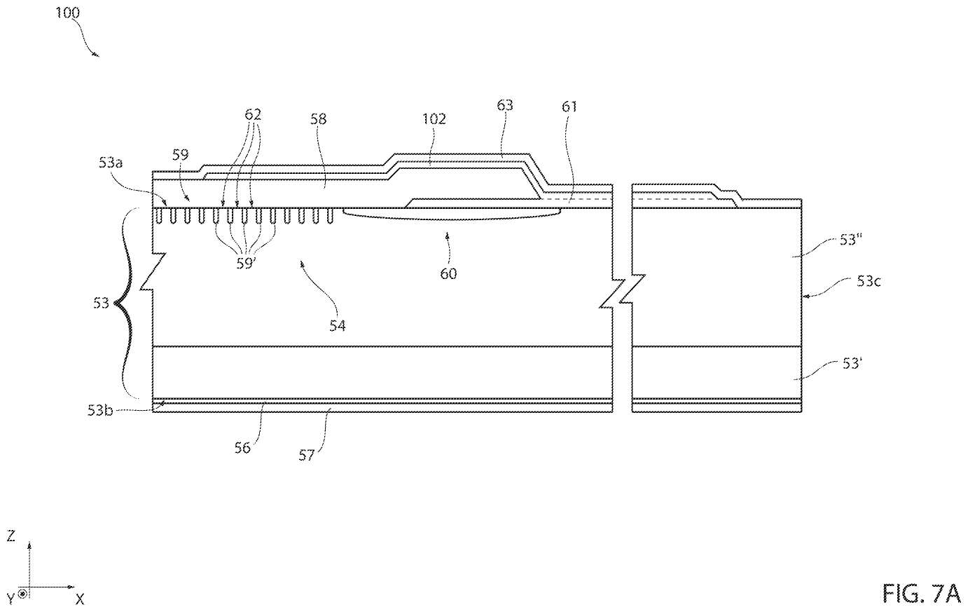

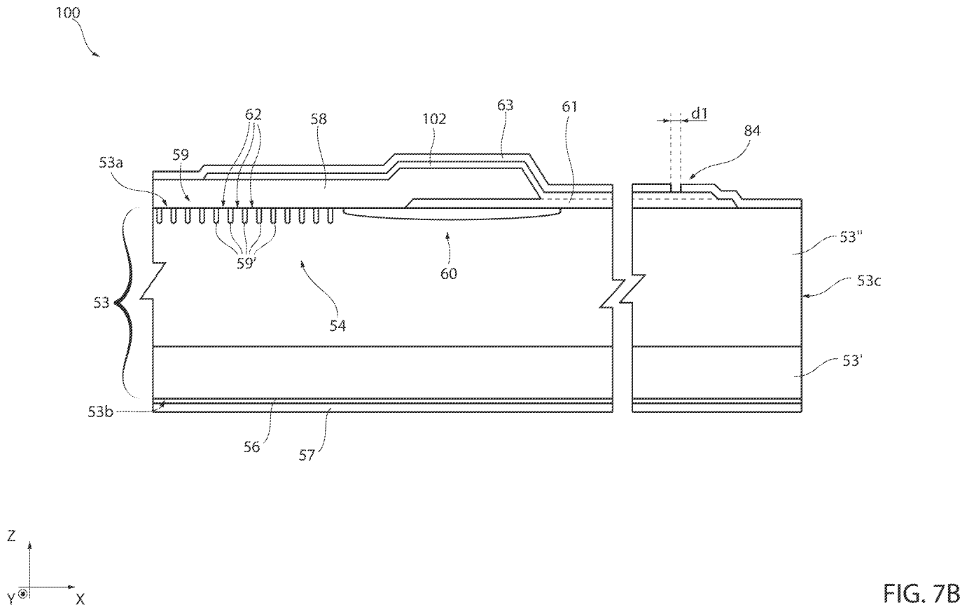

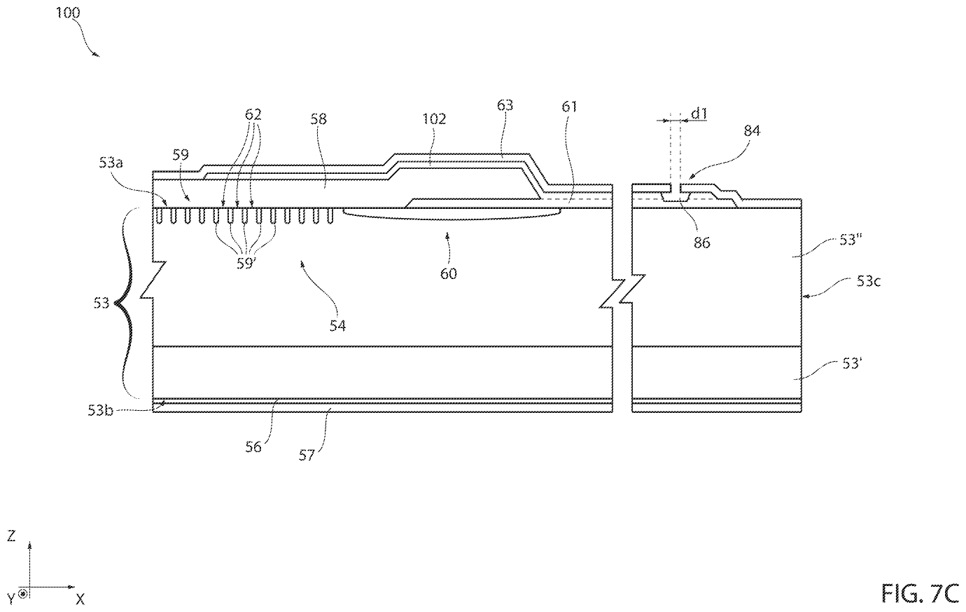

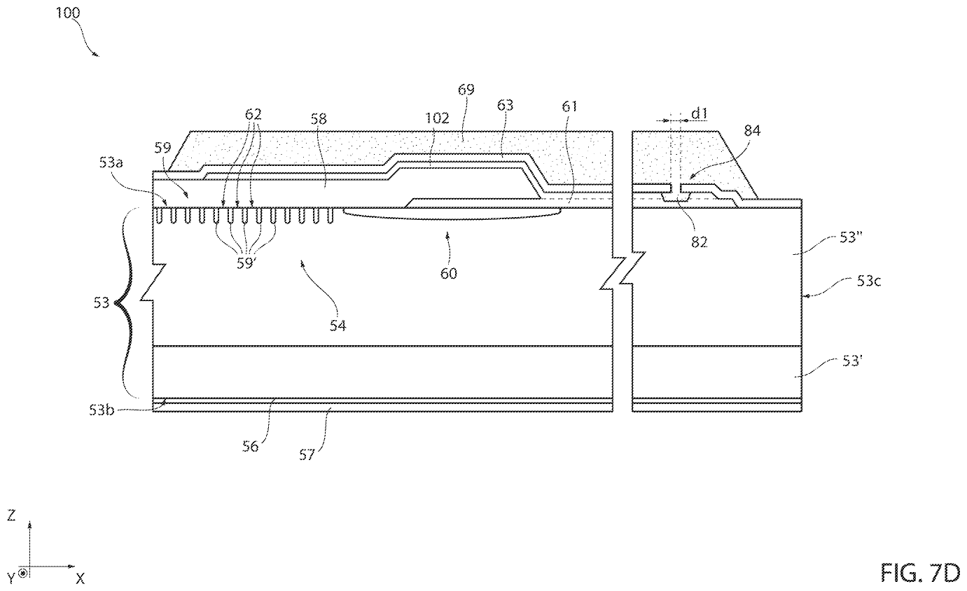

FIGS. 7A-7D show steps for manufacturing the electronic device 100 of FIG. 6 limitedly to the steps for formation of the anchoring element 82. FIGS. 7A-7D are represented in the same triaxial system of FIG. 6.

With reference to FIG. 7A, a wafer is provided that includes the SiC semiconductor body 53, following upon manufacturing steps designed to form elements of the electronic device 100 described previously (and not discussed any further herein) and identified by the same reference numbers.

With reference to FIG. 7A, after having formed the insulating layer 61 and the anode metallization, a step of deposition of insulating or dielectric material is carried out to form the insulating layer 102. This step is carried out, for example, by a CVD process. The insulating layer 102 is formed on the entire surface of the wafer and in particular covers completely the anode metallization 50 and the insulating layer 61.

Then, after formation of the insulating layer 102, the interface layer 63 is formed, for example by deposition of a CVD type of silicon nitride. The interface layer 63 is formed on the entire surface of the wafer and in particular covers completely the insulating layer 102.

Then, FIG. 7B, the interface layer 63 is selectively etched to form the opening 84. For this purpose, a photoresist mask is for example provided and, by lithographic and etching steps per se known, the opening 84 is formed having the shape, dimensions, and location discussed previously. The opening 84 extends through the interface layer 63 throughout the thickness of the latter, exposing a respective surface portion of the insulating layer 102.

Then, FIG. 7C, an etch of the insulating layer 102 is carried out through the opening 84 formed previously. The etch is, for example, of a wet type and, if an etching chemistry is used that is selective with respect to the material of the insulating layer 102 (e.g., hydrofluoric acid in the case of silicon oxide), which therefore does not remove the interface layer 63, it is possible to carry out this etch in the absence of a mask. Otherwise, it is possible to use a mask similar to the one used for the step of formation of the opening 84.

Etching of the insulating layer 102 is of an isotropic type, and, underneath the interface layer 63, the material of the insulating layer 102 is removed both vertically (along Z) and horizontally (in the plane XY). The etch is, for example, a timed etch chosen according to the type of shape that it is desired to give to the anchoring element 82. In the embodiment of FIG. 7C, etching proceeds until the insulating layer 102 is removed completely, and also proceeds with partial removal of the material of the underlying insulating layer 61. If the materials of the insulating layer 102 and of the insulating layer 61 can be etched using the same etching chemistry, removal of the portions of the insulating layer 102 and of the insulating layer 61 takes place during the same etching step; otherwise, after having removed the desired portion of the insulating layer 102, the etching chemistry changes to remove the desired portions of the insulating layer 61. As has been said, etching proceeds also laterally (along the axis X) both in the insulating layer 102 and in the insulating layer 61. A cavity 86 is thus formed in the insulating layers 102 and 61.

Then, FIG. 7D, the passivation layer 69 is formed. The polymeric material, which is liquid or semi-liquid, is applied on the wafer and distributed through spinning on the interface layer 63. During this process, the polymeric material penetrates through the opening 84 and fills completely both the cavity 86 and the opening 84. A thermal process is then carried out so that the polymeric material hardens to form the passivation layer 69 (curing process) and, simultaneously, the anchoring element 82. The polymeric material is, for example, polyimide.

The manufacturing process then continues with subsequent steps to form further elements of the electronic device 100, here not described in detail (for example, the ohmic-contact layer 56 and the cathode metallization 57).

From an examination of the characteristics of the disclosure disclosure according to the present disclosure the advantages that it allows to obtain are evident.

In particular, the anchoring element 82 guarantees adhesion of the passivation layer 69, preventing phenomena of delamination. It is thus possible to obtain the passivation layer 69 using polymeric materials, thus guaranteeing high electrical performance of the electronic device 50, 100 (due to the high dielectric strength of the passivation layer 69) and eliminating, at the same time, structural problems linked to the possible detachment of the passivation layer 69 (e.g., following upon thermal cycles or use of the electronic device 50, 100).

Consequently, the risk of damage of the electronic device 50, 100 following upon electrical discharges between metallizations set at different potentials (e.g., between the equipotential-ring or EQR metallization and the anode metallization 58) is prevented, and therefore the reliability of the electronic device 50, 100 increases, in particular when it is subject to high thermal swings and operated in a reverse-biasing condition.

The manufacturing steps described with reference to FIGS. 5A-5C and 7A-7D make it possible to obtain the electronic device 50 and, respectively, 100 comprising the respective anchoring element 82 starting from a SiC wafer. The etch carried out with reference to FIGS. 5B-5C and 7B-7D is of an isotropic type, and this allows patterning of the cavity thus formed and, consequently, of the anchoring element 82 without limitations deriving from anisotropic etching processes or from the crystallographic orientation of the SiC wafer from which the electronic device 50, 100 is obtained.

Finally, it is clear that modifications and variations may be made to the disclosure disclosure described and illustrated herein, without thereby departing from the scope of the present disclosure, as defined in the annexed claims.

A method of manufacturing an anchoring element (82) of a passivation layer (69) of an electronic device (50; 100), may be may be summarized as including the steps of forming, on a surface (53a) of a semiconductor body (53) of silicon carbide, a first insulating layer (61) of a first material; forming, in part on the surface (53a) of the semiconductor body (53) and in part on the first insulating layer (61), a layer of metal material (58); forming, on the layer of metal material (58) and on the first insulating layer (61), an interface layer (63) of a second material different from the first material; removing selective portions of the interface layer (63) at a distance from the layer of metal material (58), to form an opening (84) throughout the interface layer (63), thus exposing the first insulating layer (61); removing, through the opening (84), selective portions of the first insulating layer (61) to form a cavity (86) in the first insulating layer (61) at, and underneath, said opening (84), said cavity (86) having at least one dimension (d₁), in a direction parallel to said surface (53a), greater than a corresponding dimension of the opening (84); and simultaneously providing, on the first insulating layer (61), in the opening (84) and in the cavity (86), passivation material thus forming the passivation layer (69) on the first insulating layer (61) and said anchoring element (82) in the opening (84) and in the cavity (86).

The step of providing the passivation material may include providing the passivation material in liquid or semi-liquid form, so that the passivation material fills the cavity (86).

The step of providing the passivation material may include carrying out a step of spinning of the passivation material.

The manufacturing method may further include the step of solidifying, or curing, the passivation material, so that the anchoring element (82) and the passivation layer (69) form a single body or monolithic body.

Removing selective portions of the first insulating layer (61) may include carrying out an isotropic etching of the first insulating layer (61).

The interface layer (63) may be configured to favor adhesion of the passivation layer (69) with the insulating layer (61).

Forming the anchoring element (82) in the opening (84) and in the cavity (86) may include constraining the anchoring element (82) underneath the interface layer (63) and within the first insulating layer (61).

Forming the opening (84) may include forming an etching mask for the first insulating layer (61); the step of removing, through the opening (84), selective portions of the first insulating layer (61) including carrying out a wet etching of the first insulating layer (61).

Said cavity (86) may have a volume greater than the volume of the opening (84).

The passivation material (69) may include polymeric material.

The material of the interface layer may be silicon nitride.

Said step of forming the cavity (86) may include forming the cavity (86) throughout the thickness of the first insulating layer (61); or forming the cavity (86) through part of the thickness of the first insulating layer (61), terminating inside the first insulating layer (61).

The manufacturing method may further include the step of forming a second insulating layer (102) on the first insulating layer (61) and on the layer of metal material (58), underneath the interface layer (63).

Said step of forming the cavity (86) may further include forming the cavity (86) exclusively in the second insulating layer (102); or forming the cavity (86) completely through the second insulating layer (102) and in part through the first insulating layer (61), terminating within the first insulating layer (61); or forming the cavity (86) completely through the second insulating layer (102) and the first insulating layer (61).

Said second insulating layer (102) may be of the same material as the first insulating layer (61).

The anchoring element (82) may be formed in an electrically passive area of the electronic device, at a distance from the layer of metal material (58).

An anchoring element (82) of a passivation layer (69) of an electronic device (50; 100), may be may be summarized as including a protrusion that extends, starting from the passivation layer (69), completely through an interface layer (63) and at least in part through an insulating structure (61; 61, 102) arranged underneath the interface layer (63) on a surface (53a) of a semiconductor body (53) of silicon carbide, said protrusion terminating within the insulating structure and forming a single body, or monolithic body, with the passivation layer (69).

The anchoring element may include a first portion extending in the interface layer (63) at a first distance from the surface (53a) and having, in a direction parallel to a first axis (X; Y) parallel to the surface (53a), a maximum dimension having a first value (d₁); and a second portion extending in the insulating structure in structural continuation of the first portion and having, in a direction parallel to the first axis (X; Y), a respective maximum dimension having a second value greater than the first value (d₁).

Said second portion of the anchoring element may extend in part inside or completely through the insulating structure (61, 102).

The passivation material (69) may include polymeric material.

The anchoring element (82) may extend in an electrically passive area of the electronic device (50; 100).

An electronic device (50; 100), may be may be summarized as including a semiconductor body (53) of silicon carbide; a first insulating layer (61; 102), of a first material, on a surface (53a) of the semiconductor body (53); a layer of metal material (58) extending in part on the surface (53a) of the semiconductor body (53) and in part on the first insulating layer (61); an interface layer (63) on the first insulating layer (61) and on the layer of metal material (58), consisting of a second material different from the first material; a passivation layer (69) on the interface layer (63); and an anchoring element (82) that protrudes from the passivation layer (69) towards the first insulating layer (61; 102) and extends completely through an opening (84) of the interface layer (63) and terminates within the first insulating layer (61; 102), said anchoring element (82) having at least one dimension (d₁), in a direction parallel to said surface (53a), greater than a corresponding dimension of the opening (84).

The anchoring element (82) and the passivation layer (69) may form a single body, or monolithic body.

The interface layer (63) may be configured to favor adhesion of the passivation layer (69) with the insulating layer (61).

The anchoring element (82) may be configured to constrain the passivation layer (69) underneath the interface layer (63) and within the first insulating layer (61).

The anchoring element (82) may include a first portion extending in the insulating structure at a first distance from the surface (53a) and having, in a direction parallel to a first axis (X; Y) parallel to the surface (53a), a maximum dimension having a first value (d₁); and a second portion extending in the insulating structure in structural continuation of the first portion and having, in a direction parallel to the first axis (X; Y), a respective maximum dimension having a second value greater than the first value (d₁).

The passivation material (69) may include polymeric material.

The material of the interface layer (63) may be silicon nitride.

The anchoring element (82) may extend throughout the thickness of the interface layer (63) and of the first insulating layer (61); or throughout the thickness of the interface layer (63) and part of the thickness of the first insulating layer (61), terminating within the first insulating layer (61).

The electronic device may further include a second insulating layer (102) on the first insulating layer (61) and on the layer of metal material (58).

The anchoring element (82) may extend throughout the thickness of the interface layer (63) and: in the second insulating layer (102) terminating within the second insulating layer (102); or completely through the second insulating layer (102) and in part in the first insulating layer (61), terminating within the first insulating layer (61); or completely through the second insulating layer (102) and the first insulating layer (61), terminating at the surface (53a) of the semiconductor body (53).

The anchoring element (82) may extend in an electrically passive area of the electronic device (50; 100).

The electronic device chosen in the group may include a Schottky diode, a PiN diode, a PN diode, an MPS device, a JBS diode, a MOSFET, an IGBT, or a power device.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming, on a surface of a semiconductor body of silicon carbide, a first insulating layer of a first material;
forming, in part on the surface of the semiconductor body and in part on the first insulating layer, a layer of conductive material;
forming, on the layer of conductive material and on the first insulating layer, an interface layer of a second material different from the first material;
removing selective portions of the interface layer at a distance from the layer of metal material, forming an opening extending through the interface layer and exposing the first insulating layer with the opening;
removing, through the opening, selective portions of the first insulating layer to form a cavity in the first insulating layer at, and underneath, the opening, the cavity having at least one dimension, in a direction parallel to the surface, of the semiconductor body greater than a corresponding dimension of the opening, in the direction; and
forming, on the first insulating layer, in the opening, and in the cavity, a passivation material forming a passivation layer on the first insulating layer and an anchoring element in the opening and in the cavity.

2. The method according to claim 1, further comprising curing the passivation material so that the anchoring element and the passivation layer form a monolithic body.

3. The method according to claim 1, wherein removing selective portions of the first insulating layer comprises carrying out an isotropic etching on the first insulating layer.

4. The method according to claim 1, wherein the interface layer couples the passivation layer to the insulating layer, and the interface layer is configured to favor adhesion of the passivation layer with the insulating layer.

5. The manufacturing method according to claim 1, wherein forming the anchoring element in the opening and in the cavity comprises constraining the anchoring element underneath the interface layer and within the first insulating layer.

6. The manufacturing method according to claim 1, wherein forming the opening comprises forming an etching mask for the first insulating layer;
removing, through the opening, selective portions of the first insulating layer including carrying out a wet etching of the first insulating layer.

7. The method according to claim 1, wherein forming the cavity comprises forming the cavity throughout the thickness of the first insulating layer.

8. The method according to claim 1, wherein forming the cavity comprising forming the cavity through part of the thickness of the first insulating layer, terminating inside the first insulating layer before reaching the surface of the semiconductor body.

9. The method according to claim 1, further comprising forming a second insulating layer on the first insulating layer and on the layer of metal material, and wherein forming the interface layer further comprises forming the interface layer on and covering the second insulating layer.

10. The method according to claim 9, wherein forming the cavity further comprises forming the cavity exclusively in the second insulating layer.

11. The method according to claim 9, wherein forming the cavity further comprises forming the cavity completely through the second insulating layer and in part through the first insulating layer, terminating within the first insulating layer.

12. The method according to claim 9, wherein forming the cavity further comprises forming the cavity completely through the second insulating layer and the first insulating layer.

13. The manufacturing method according to claim 9, wherein said second insulating layer is of the same material as the first insulating layer.

14. A device, comprising:
a semiconductor body of silicon carbide including a surface;
an insulating structure on the surface of the semiconductor body;
an interface layer on the insulating structure;
a passivation layer on the interface layer, the passivation layer having an anchoring element including:
a protrusion that extends, starting from the passivation layer, completely through the interface layer and at least in part through the insulating structure, the protrusion terminates within the insulating structure before reaching the surface of the semiconductor body and has a monolithic body with the passivation layer.

15. The anchoring element according to claim 14, comprising:
a first portion extending in the interface layer at a first distance from the surface and having, in a direction parallel to a first axis parallel to the surface, a maximum dimension having a first value; and
a second portion extending in the insulating structure in structural continuation of the first portion and having, in a direction parallel to the first axis, a respective maximum dimension having a second value greater than the first value.

16. The anchoring element according to claim 15, wherein said second portion of the anchoring element extends in part inside or completely through the insulating structure.

17. A device, comprising:
a semiconductor body of silicon carbide including a surface;
a first insulating layer, of a first material, on the surface of the semiconductor body;
a layer of metal material extending in part on the surface of the semiconductor body and in part on the first insulating layer;
an interface layer on the first insulating layer and on the layer of metal material, the interface layer is made of a second material different from the first material;
a passivation layer on the interface layer; and
an anchoring element of the passivation layer that protrudes towards the first insulating layer and extends completely through an opening of the interface layer and terminates within the first insulating layer, said anchoring element having at least one dimension, in a direction parallel to said surface, greater than a corresponding dimension of the opening.

18. The electronic device according to claim 17, wherein the interface layer couples the passivation layer to the insulating layer, and the interface layer is configured to favor adhesion of the passivation layer with the insulating layer.

19. The electronic device according to claim 17, wherein the anchoring element extends throughout a first thickness of the interface layer and a second thickness of the first insulating layer.

20. The device according to claim 17, wherein the anchoring element extends throughout a first thickness of the interface layer and part of a second thickness of the first insulating layer, and the anchoring element terminates within the first insulating layer before reaching the surface of the semiconductor body.
